(19) United States
(12) Patent Application Publication
(10) Pub. No.: US 2026/0076167 A1
(43) Pub. Date: Mar. 12, 2026

(54) INTERCONNECT STRUCTURE FOR SEMICONDUCTOR DEVICE WITH AIRGAP

(71) Applicant: International Business Machines Corporation, Armonk, NY (US)

(72) Inventors: Abir Shadman, Albany, NY (US); Koichi Motoyama, Clifton Park, NY (US); Shay Reboh, Guilderland, NY (US); Nicholas Anthony Lanzillo, Wynantskill, NY (US)

(21) Appl. No.: 18/828,287

(22) Filed: Sep. 9, 2024

(51) Int. Cl. H01L 23/528; H01L 21/768; H01L 23/532

(52) U.S. Cl. CPC H10W 20/43; H10W 20/054; H10W 20/072; H10W 20/076; H10W 20/425; H10W 20/46

(57) ABSTRACT

A semiconductor device includes a substrate, a plurality of metal lines on the substrate, a protuberance layer formed on upper portions of sidewalls of the metal lines, and a liner layer formed between the metal lines and between the protuberance layer. The liner layer connects the protuberance layer, and an airgap exists in the liner layer below a bottom surface of the protuberance layers.

### BACKGROUND

The present disclosure relates to fabrication methods and resulting structures for semiconductor devices. More specifically, the present disclosure relates to interconnect structures including an airgap between adjacent metal lines and within a dielectric liner layer. The present disclosure also provides methods of fabricating such an interconnect structure.

The speed of propagation of interconnect signals is one of the most important factors controlling overall circuit speed as feature sizes are reduced and the number of devices per unit area as well as the number of interconnect levels are increased. Throughout the semiconductor industry, there has been a strong drive to increase the aspect ratio (i.e., height to width ratio) and to reduce the dielectric constant, low-κ, of the interlayer dielectric (ILD) materials used to electrically insulate the conductive metal lines. As a result, interconnect signals travel faster through conductors due to a reduction in resistance-capacitance (RC) delays. It may be desirable to further lower the effective dielectric constant of the interconnect structure to further improve the signal speed of the interconnect structures.

### SUMMARY

Embodiments of the present disclosure relate to a semiconductor device. The semiconductor device includes Embodiments a semiconductor device comprising a substrate, a plurality of metal lines on the substrate, a protuberance layer formed on upper portions of sidewalls of the metal lines, and a liner layer formed between the metal lines and between the protuberance layer. The liner layer connects the protuberance layer, and an airgap exists in the liner layer below a bottom surface of the protuberance layer.

Embodiments of the present disclosure relate to method of manufacturing a semiconductor device. The methods include forming a plurality of metal lines on a substrate; forming a protuberance layer on upper portions of sidewalls of the metal lines; and forming a liner layer between the metal lines and between the protuberance layer, the liner layer connecting the protuberance layer, wherein an airgap exists in the liner layer below a bottom surface of the protuberance layer.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1 is a partial cross-sectional view of a semiconductor device at an intermediate stage of the fabrication process, according to embodiments.

FIG. 2 is a partial cross-sectional view of the semiconductor device of FIG. 1 at subsequent stage of the fabrication process, according to embodiments.

FIG. 3 is a partial cross-sectional view of the semiconductor device of FIG. 2 at subsequent stage of the fabrication process, according to embodiments.

FIG. 4 is a partial cross-sectional view of the semiconductor device of FIG. 3 at subsequent stage of the fabrication process, according to embodiments.

FIG. 5 is a partial cross-sectional view of the semiconductor device of FIG. 4 at subsequent stage of the fabrication process, according to embodiments.

FIG. 6 is a partial cross-sectional view of the semiconductor device of FIG. 5 at subsequent stage of the fabrication process, according to embodiments.

FIG. 7 is a partial cross-sectional view of the semiconductor device of FIG. 6 at subsequent stage of the fabrication process, according to embodiments.

FIG. 8 is a partial cross-sectional view of a comparative example of a semiconductor device without the protuberance layer and illustrating a relatively smaller air gap, according to embodiments.

FIG. 9 is a partial cross-sectional view of a semiconductor device at an intermediate stage of the fabrication process, according to embodiments.

FIG. 10 is a partial cross-sectional view of the semiconductor device of FIG. 9 at subsequent stage of the fabrication process, according to embodiments.

FIG. 11 is a partial cross-sectional view of the semiconductor device of FIG. 10 at subsequent stage of the fabrication process, according to embodiments.

FIG. 12 is a partial cross-sectional view of the semiconductor device of FIG. 11 at subsequent stage of the fabrication process, according to embodiments.

FIG. 13 is a partial cross-sectional view of the semiconductor device of FIG. 12 at subsequent stage of the fabrication process, according to embodiments.

FIG. 14 is a partial cross-sectional view of the semiconductor device of FIG. 13 at subsequent stage of the fabrication process, according to embodiments.

FIG. 15 is a partial cross-sectional view of the semiconductor device of FIG. 14 at subsequent stage of the fabrication process, according to embodiments.

FIG. 16 is a partial cross-sectional view of the semiconductor device of FIG. 15 at subsequent stage of the fabrication process, according to embodiments.

FIG. 17 is a partial cross-sectional view of the semiconductor device of FIG. 16 at subsequent stage of the fabrication process, according to embodiments.

### DETAILED DESCRIPTION

The present disclosure describes semiconductor devices. More specifically, the present disclosure relates to interconnect structures including a protuberance at an upper side of a metal line and at least one airgap existing within a dielectric liner layer and between adjacent metal lines. The present disclosure also provides methods of fabricating such interconnect structures.

The flowcharts and cross-sectional diagrams in the Figures illustrate methods of manufacturing semiconductor devices according to various embodiments. In some alternative implementations, the manufacturing steps may occur in a different order than that is noted in the Figures, and certain additional manufacturing steps may be implemented between the steps noted in the Figures. Moreover, any of the layered structures depicted in the Figures may contain multiple sublayers.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the particular drawing figures. Several of the figures show different orientation such as the top view, and different cross-sectional views. It should be noted that right and left, or top and bottom, etc. relate to (or depend on) the particular view of each figure. The terms “overlying,” “atop,” “on top,” “positioned on” or “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography. Deposition is any process that grows, coats, or otherwise transfers a material onto the wafer. Available technologies include physical vapor deposition (PVD), chemical vapor deposition (CVD), electrochemical deposition (ECD), molecular beam epitaxy (MBE) and more recently, atomic layer deposition (ALD) among others. Removal/etching is any process that removes material from the wafer. Examples include etch processes (either wet or dry), and chemical-mechanical planarization (CMP), and the like. Semiconductor doping is the modification of electrical properties by doping, for example, transistor sources and drains, generally by diffusion and/or by ion implantation. These doping processes are followed by furnace annealing or by rapid thermal annealing (RTA). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device. Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, state-of-the-art semiconductor chips employ copper (Cu) as an electrical conductor and inorganic organosilicates as a low dielectric constant (low-κ) dielectric material, and the semiconductor chips may include, for example, twelve or more levels of Cu/low-κ interconnect layers. These Cu/low-κ interconnect layers are fabricated with an iterative additive process, called dual-damascene, which includes several processing steps. For example, a typical dual-damascene process includes film deposition, patterning by lithography and reactive ion etching, liner deposition, Cu metal fill by electrochemical plating, and chemical-mechanical polishing of excessive Cu metal.

When fabricating integrated circuit wirings within a multi-layered scheme, an insulating or dielectric material, e.g., silicon oxide or a low-κ insulator will normally be patterned with several thousand openings to create conductive line openings and/or via openings using photo patterning and plasma etching techniques, e.g., photolithography with subsequent etching by plasma processes. The via openings are typically filled with a conductive metal material (e.g., aluminum, copper, etc.) to electrically interconnect the active and/or passive elements of the integrated circuits. The semiconductor device is then polished to level its surface.

Methods to introduce low-κ materials (typically dielectrics whose dielectric constant is below that of silicon oxide) into advanced interconnects may be difficult to implement due to the characteristics of the low-κ materials that are being introduced. Moreover, low-κ dielectrics exhibit fundamentally weaker electrical and mechanical properties as compared to silicon oxide. Moreover, the low-κ dielectric alternatives are typically susceptible to damage during the various interconnect processing steps. The damage observed in the low-κ dielectric materials is manifested by an increase in the dielectric constant and increased moisture uptake, which may result in reduced performance and device reliability.

Airgaps may be used as means for lowering the effective dielectric constant of the interconnect structure. Lowering the effective dielectric constant of an interconnect structure may be important in the semiconductor industry because such structures have an even lower electrical resistance associated therewith. With certain interconnect structures, airgaps may be introduced into the structure utilizing many additional processing steps, which raise the production cost of the structure being manufactured. The present embodiments provide improved methods of fabricating an airgap-containing interconnect structure which may reduce the overall number of processing steps and increase an overall electrical resistance of the interconnect wiring layers of the semiconductor device.

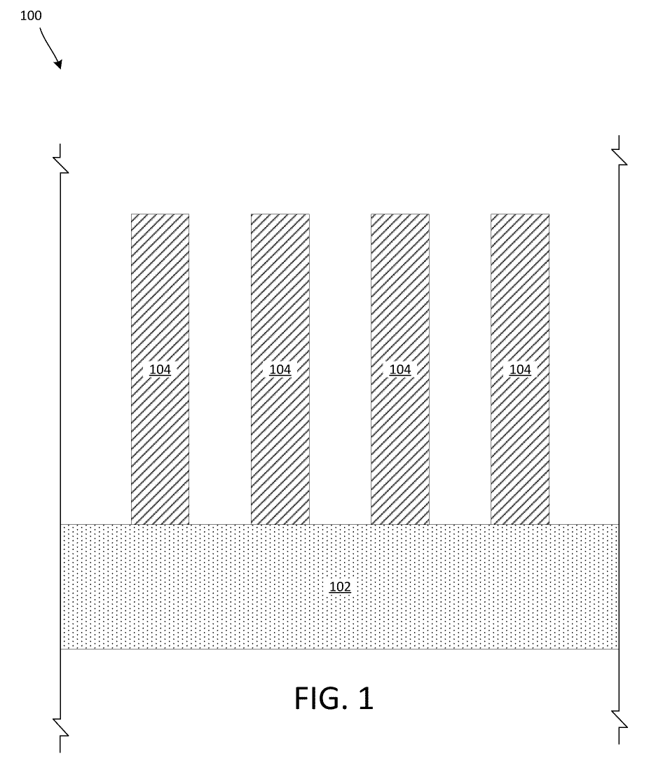

Referring now to the drawings in which like numerals represent the same or similar elements and initially to FIG. 1, this figure is a partial cross-sectional view of a semiconductor device 100 at an intermediate stage of the fabrication process, according to embodiments. As shown in FIG. 1, a substrate 102 is provided. The substrate 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 102 may also be a semiconductor on insulator (SOI) substrate. Other illustrative examples of semiconductor materials that can be used in the present application include, but are not limited to, silicon (Si), a silicon germanium (SiGe) alloy, a silicon germanium carbide (SiGeC) alloy, germanium (Ge), a III/V compound semiconductor, an II/VI compound semiconductor or a multilayered stack including at least two semiconductor materials (e.g., a multilayered stack of Si and SiGe). In one embodiment (depicted in the drawings of the present application), the semiconductor substrate 102 is entirely composed of at least one semiconductor material. When the substrate 102 is an insulating material, the insulating material can be an organic insulator, an inorganic insulator or a combination thereof including multilayers. The substrate 102 may also include a patternable low-κ dielectric material as well. When the substrate 102 is a conducting material, the substrate may include, for example, polySi, an elemental metal, alloys of elemental metals, a metal silicide, a metal nitride, conductive nanotubes and nanowires or combinations thereof including multilayers. When the substrate 102 comprises a semiconducting material, one or more semiconductor devices such as, for example, complementary metal oxide semiconductor (CMOS) devices can be fabricated thereon. It should be appreciated that the substrate 102 may be comprised of any other suitable material(s) than those listed above.

Referring again to FIG. 1, the semiconductor device 100 includes a plurality of metal lines 104 formed on the substrate 102. In certain embodiments, the metal lines 104 are formed by a subtractive method. In other embodiments, the metal lines 104 may be formed by a via fill and etching process applied to an interlayer dielectric (ILD) layer (not shown). It should be appreciated that the metal lines 104 may be formed by any suitable combination of patterning, lithography, deposition and material removal processes. In certain embodiments, the metal lines 104 comprise Cu, however any suitable electrically conductive materials may be used.

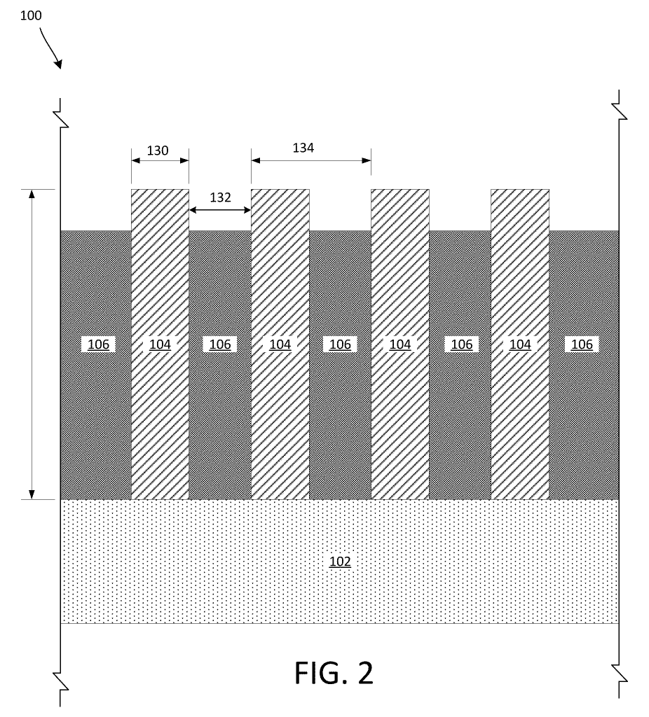

Referring now to FIG. 2, this figure is a partial cross-sectional view of the semiconductor device 100 of FIG. 1 at subsequent stage of the fabrication process, according to embodiments. As shown in FIG. 2, a sacrificial material layer 106 is deposited to fill in the spaces between the metal lines 104. In certain examples, the sacrificial material layer 106 may comprise a spin on glass (SOG) insulator, a furnace chemical vapor deposition (FCVD) material, etc. In certain embodiments, as shown in FIG. 2, the top surface of the sacrificial material layer 106 is below the top surface of the metal lines 104. In this way, the tops of the metal lines 104 are exposed for further processing. In certain examples, the sacrificial material layer 106 may initially be formed in excess to cover the top surfaces of the metal lines 104. In these examples, excess material of the sacrificial material layer 106 may be removed with any suitable material removal process (e.g., CMP) down to the level of the top surface of the metal lines 104 to planarize the overall surface of the semiconductor device 100. Then, another material removal process may be used to selectively remove some of the material of the sacrificial material layer 106 so that they are recessed relative to the metal lines 104 (i.e., the top surface of the sacrificial material layer 106 is below the top surface of the metal lines 104). In certain examples, a width 130 of the metal lines 104 may be from about 5-10 nm, a distance 132 between the metal lines 104 (i.e., which also corresponds to the width of the sacrificial material layer 106) may be from about 5-10 nm, the pitch 134 of the metal lines 104 may be about 10-20 nm, and the height 136 of the metal lines 104 may be about 20-40 nm. However, it should be appreciated that other suitable dimensions for these layers may be used. As will be described in further detail below, after the sacrificial material layer 106 is later removed, there will again be empty space between the adjacent metal lines 104.

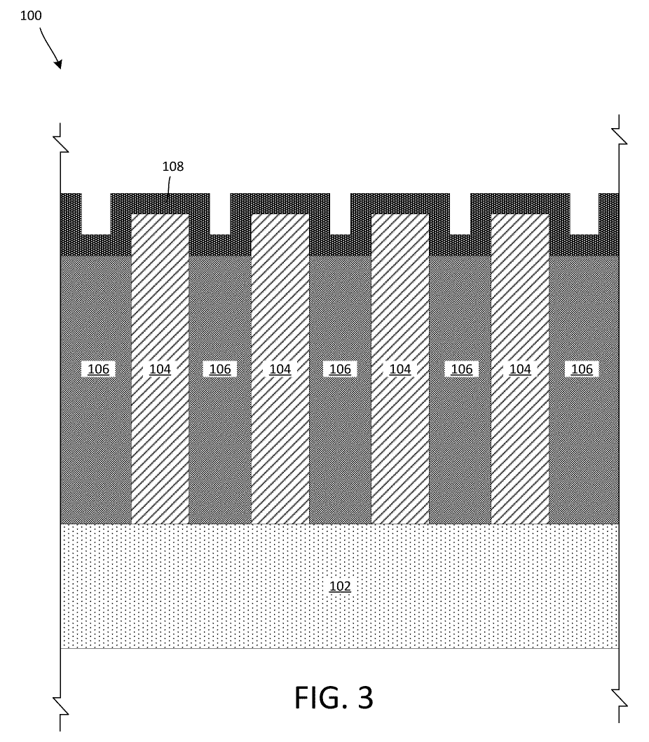

Referring now to FIG. 3, this figure is a partial cross-sectional view of the semiconductor device 100 of FIG. 2 at subsequent stage of the fabrication process, according to embodiments. As shown in FIG. 3 a protuberance layer 108 (or liner layer) is conformally deposited onto the top surfaces of the metal lines 104 and the sacrificial material layer 106. In certain examples, the protuberance layer 108 may comprise any suitable dielectric or metallic material(s).

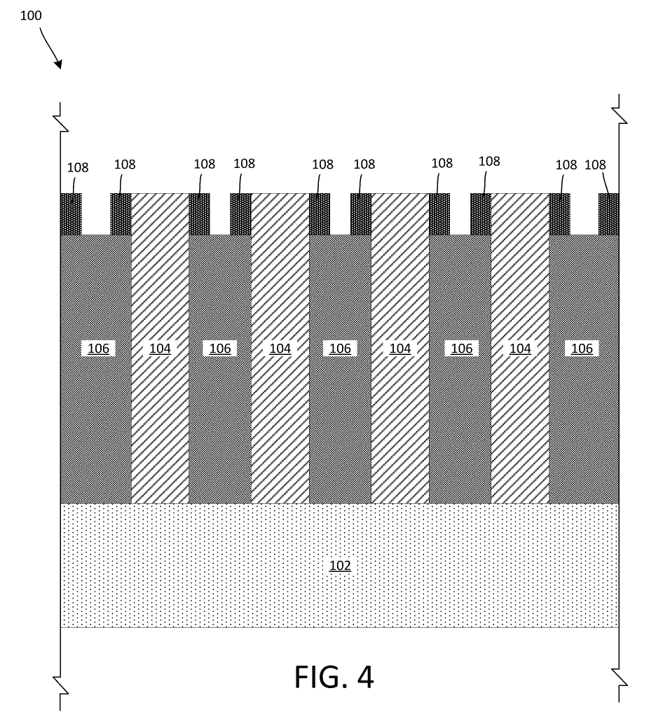

Referring now to FIG. 4, this figure is a partial cross-sectional view of the semiconductor device 100 of FIG. 3 at subsequent stage of the fabrication process, according to embodiments. As shown in FIG. 4, a suitable material removal process (e.g., anisotropic etching) is performed to remove the horizontal portions of the protuberance layer 108, thus leaving only the sidewall portions of the protuberance layer 108 remaining. These sidewall portions of the protuberance layer 108 may also be referred to as sidewall spacers.

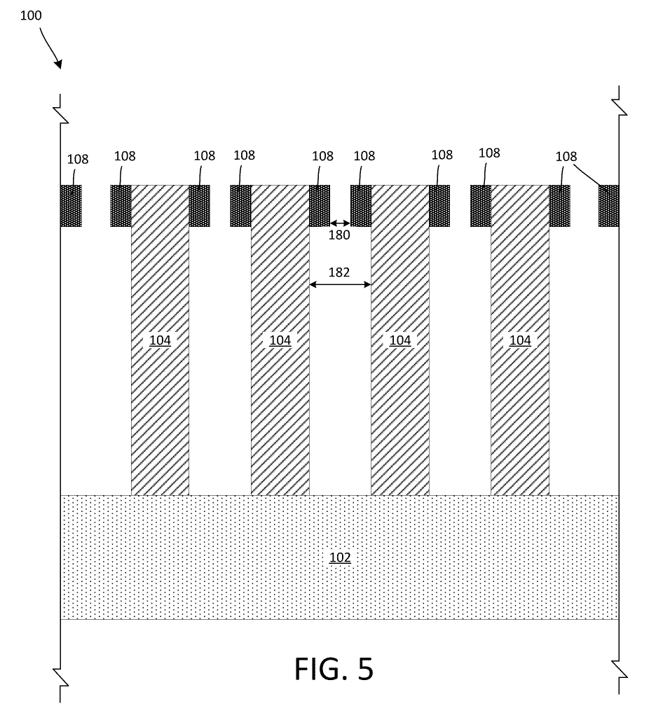

Referring now to FIG. 5, this figure is a partial cross-sectional view of the semiconductor device 100 of FIG. 4 at subsequent stage of the fabrication process, according to embodiments. As shown in FIG. 5, a suitable material removal process is performed to remove the sacrificial material layer 106. Thus, after the removal of the sacrificial layer 106, there is a first distance 180 between adjacent sections of the protuberance layers 108 that is less than a second distance 182 between adjacent metal lines 104.

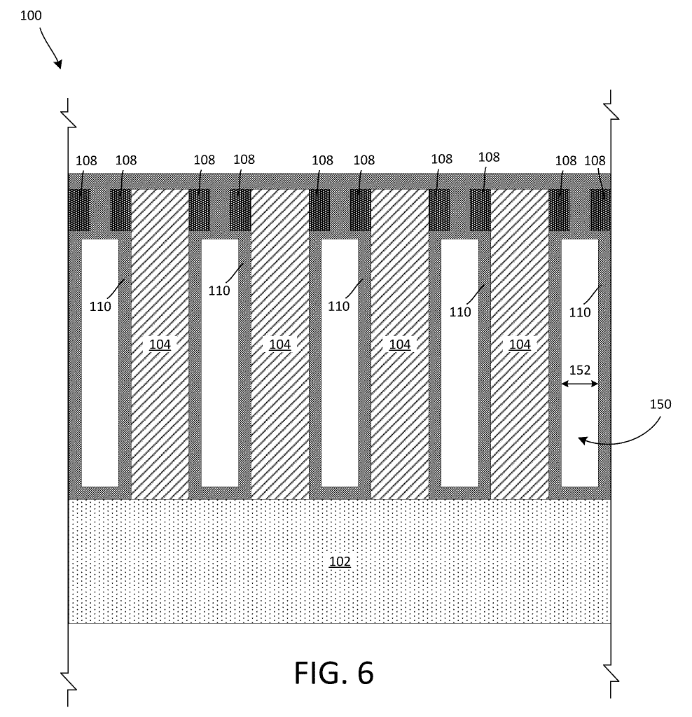

Referring now to FIG. 6, this figure is a partial cross-sectional view of the semiconductor device 100 of FIG. 5 at subsequent stage of the fabrication process, according to embodiments. As shown in FIG. 6, a material deposition process is performed to create a dielectric liner layer 110 on the sidewalls of the protuberance layers 108 and the sidewalls of the metal lines 104. It should be appreciated that any suitable dielectric material(s) may be used to form the dielectric liner layer 110. As discussed with respect to FIG. 5, the first distance 180 between adjacent sections of the protuberance layers 108 is less than the second distance 182 between adjacent metal lines 104. Thus, when the material of the dielectric liner layer 110 is deposited, the space (i.e., corresponding to the first distance 180 shown in FIG. 5) between the adjacent protuberance layers 108 will close off before completely filling in the space (i.e., corresponding to the second distance 182 shown in FIG. 5) between the adjacent metal lines 104, thus leaving an air gap 150 with a width of 152.

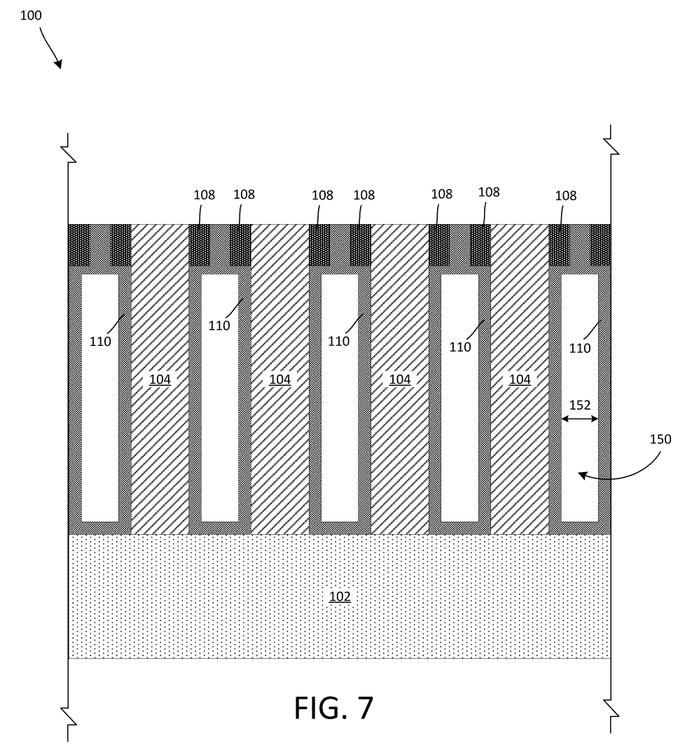

Referring now to FIG. 7, this figure is a partial cross-sectional view of the semiconductor device 100 of FIG. 6 at subsequent stage of the fabrication process, according to embodiments. As shown in FIG. 7, after the deposition of the dielectric liner layer 110 a suitable material removal process (e.g., CMP) is performed to planarize the top surface of the semiconductor device 100 and to remove excess material of the dielectric liner layer 110 that was previously formed on the top of the metal lines 104 and the top of the protuberance layer 108.

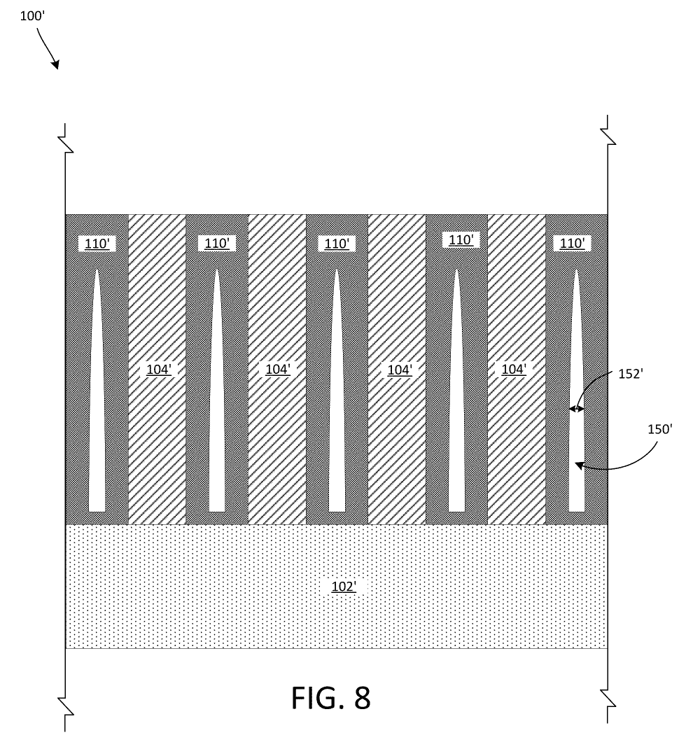

Referring now to FIG. 8, this figure is a partial cross-sectional view of a comparative example of a semiconductor device 100’ without the inclusion of the protuberance layer 108. As shown in FIG. 8, because there is no protuberance layer 108, more material must be deposited in order to close off (or pinch off) the upper portion of the dielectric liner layer 110’. This may result in a much smaller (or even non-existent) air gap 150’ having a smaller average width 152’. In one example, the air gaps 150’ may be slightly tapered as shown in FIG. 8, while in other embodiments, the air gaps 150’ will be generally rectangular.

However, in contrast to the comparative example shown in FIG. 8 and as shown in the embodiments related to FIGS. 1-7, a larger air gap 150 having a larger width 152 is able to be formed owing to the protuberance layer 108. In this regard, less material of the dielectric liner layer 110 needs to be deposited (i.e., relative to the comparative example shown in FIG. 8) in order to close off (or pinch off) the upper portion of the dielectric liner layer 110 that is between the protuberance layer 108. In general, the dielectric constant of air is 1.0, which is significantly lower than that of any solid material used in semiconductor fabrication. Thus, incorporation of a relatively larger air gap 150 as shown in FIG. 7 (i.e., relative to air gap 150’ shown in FIG. 8) having a larger width 152 inside the dielectric liner layer 110 allows for the lowering of the overall effective dielectric constant for the semiconductor device 100, which may improve device performance.

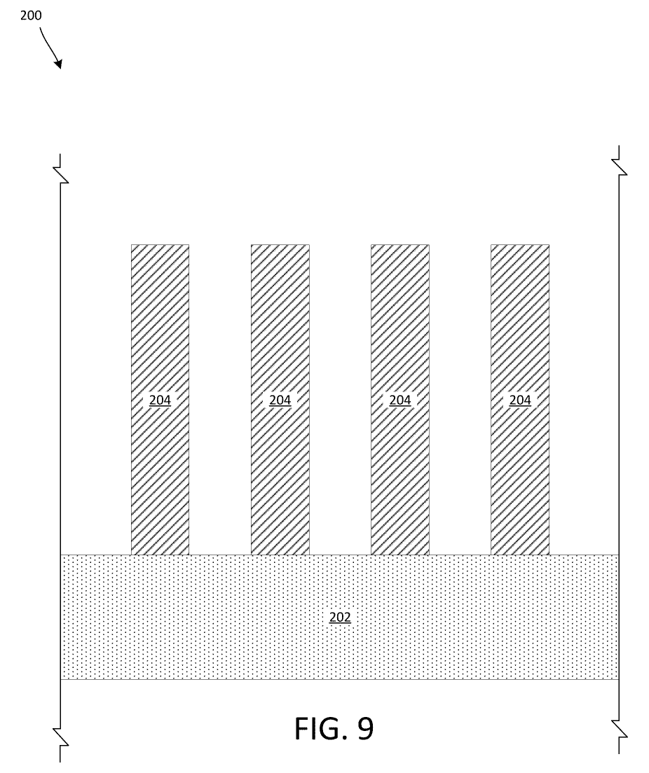

Referring now to FIG. 9, this figure is a partial cross-sectional view of a semiconductor device 200 at an intermediate stage of the fabrication process, according to embodiments. As shown in FIG. 9, a substrate 202 is provided. The substrate 202 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 202 may also be a semiconductor on insulator (SOI) substrate. Other illustrative examples of semiconductor materials that can be used in the present application include, but are not limited to, silicon (Si), a silicon germanium (SiGe) alloy, a silicon germanium carbide (SiGeC) alloy, germanium (Ge), a III/V compound semiconductor, an II/VI compound semiconductor or a multilayered stack including at least two semiconductor materials (e.g., a multilayered stack of Si and SiGe). In one embodiment (depicted in the drawings of the present application), the semiconductor substrate 202 is entirely composed of at least one semiconductor material. When the substrate 202 is an insulating material, the insulating material can be an organic insulator, an inorganic insulator or a combination thereof including multilayers. The substrate 202 may also include a patternable low-κ dielectric material as well. When the substrate 202 is a conducting material, the substrate may include, for example, polySi, an elemental metal, alloys of elemental metals, a metal silicide, a metal nitride, conductive nanotubes and nanowires or combinations thereof including multilayers. When the substrate 102 comprises a semiconducting material, one or more semiconductor devices such as, for example, complementary metal oxide semiconductor (CMOS) devices can be fabricated thereon. It should be appreciated that the substrate 202 may be comprised of any other suitable material(s) than those listed above.

Referring again to FIG. 9, the semiconductor device 200 includes a plurality of metal lines 204 formed on the substrate 202. In certain embodiments, the metal lines 204 are formed by a subtractive method. In other embodiments, the metal lines 204 may be formed by a via fill and etching process applied to an interlayer dielectric (ILD) layer (not shown). It should be appreciated that the metal lines 204 may be formed by any suitable combination of patterning, lithography, deposition and material removal processes. In certain embodiments, the metal lines 204 comprise Cu, however any suitable electrically conductive materials may be used.

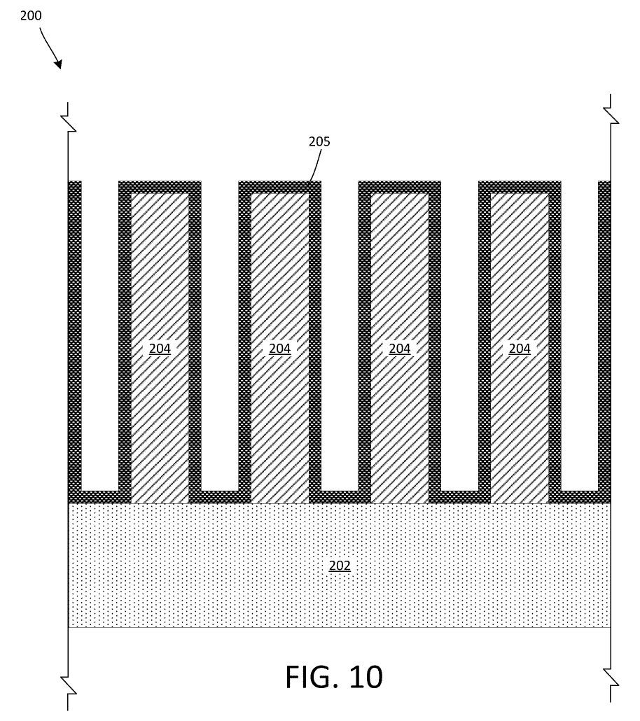

Referring now to FIG. 10, this figure is a partial cross-sectional view of the semiconductor device 200 of FIG. 9 at subsequent stage of the fabrication process, according to embodiments. As shown in FIG. 10, a liner layer 205 is conformally deposited on the substrate 202 and all exposed surfaces of the metal lines 204. In certain examples, the liner layer 205 may comprise SiN. However, it should be appreciated that any suitable material(s) may be used for the liner layer 205.

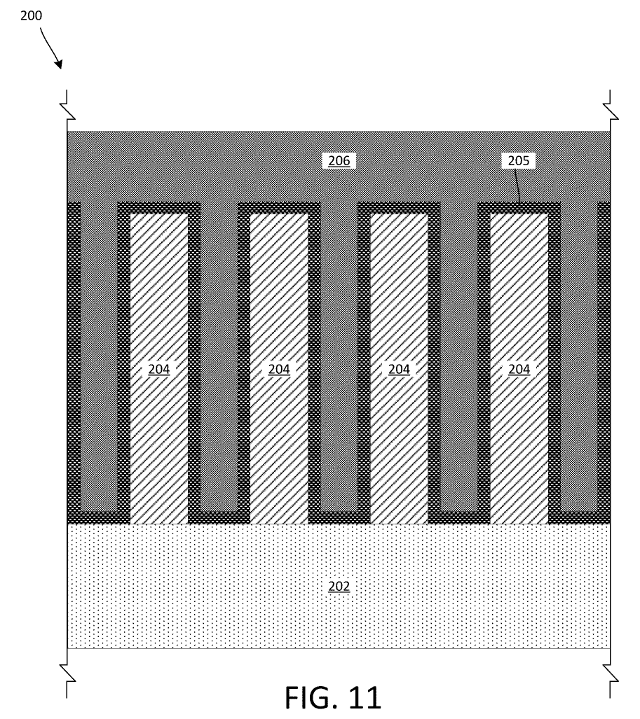

Referring now to FIG. 11, this figure is a partial cross-sectional view of the semiconductor device 200 of FIG. 10 at subsequent stage of the fabrication process, according to embodiments. As shown in FIG. 11, a sacrificial material layer 206 is deposited to fill in the spaces between the metal lines 204. In certain embodiments, as shown in FIG. 10, the top surface of the sacrificial material layer 206 is above the top surface of the metal lines 204.

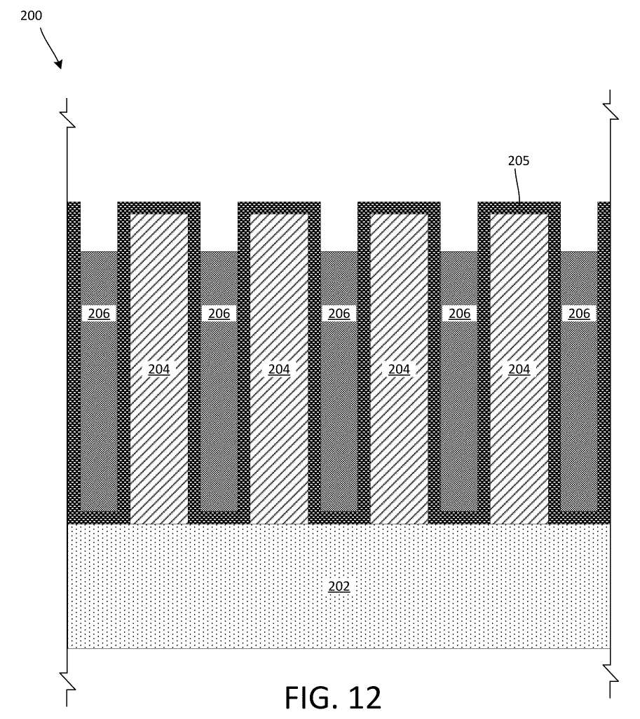

Referring now to FIG. 12, this figure is a partial cross-sectional view of the semiconductor device 200 of FIG. 11 at subsequent stage of the fabrication process, according to embodiments. As shown in FIG. 12, excess material of the sacrificial material layer 206 is removed with any suitable material removal process (e.g., CMP) down to the level of the top surface of the metal lines 204 to planarize the overall surface of the semiconductor device 200. Then, another material removal process may be used to selectively remove some of the material of the sacrificial material layer 206 so that they are recessed relative to the metal lines 204 (i.e., the top surface of the sacrificial material layer 206 is below the top surface of the metal lines 204). The heights, widths and pitch between adjacent metal lines 204 may be the same or different as in the embodiments related to FIGS. 1-7. As will be described in further detail below, after the sacrificial material layer 206 is later removed, there will again be empty space between the adjacent metal lines 204.

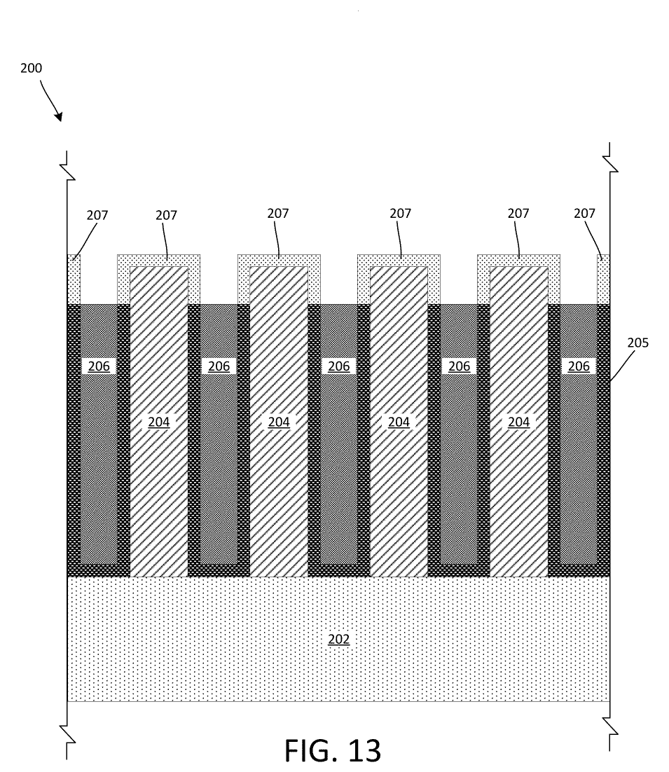

Referring now to FIG. 13, this figure is a partial cross-sectional view of the semiconductor device 200 of FIG. 12 at subsequent stage of the fabrication process, according to embodiments. As shown in FIG. 13, after the excess material of the sacrificial layer 206 has been removed, a manufacturing process is performed to transform a top portion of the liner layer 205 (i.e., the portion of the liner layer 205 that is exposed during the previous recessing of the sacrificial layer 206) to become a protuberance layer 207. In certain examples, where the material of the liner layer 205 is includes SiN (or the like), a plasma oxidation process is performed to convert the top portion of the liner layer 205 into the protuberance layer 207. In other examples, where the material of the liner layer 205 is includes SiO₂ (or the like), a plasma nitridation process is performed to convert the top portion of the liner layer 205 into the protuberance layer 207.

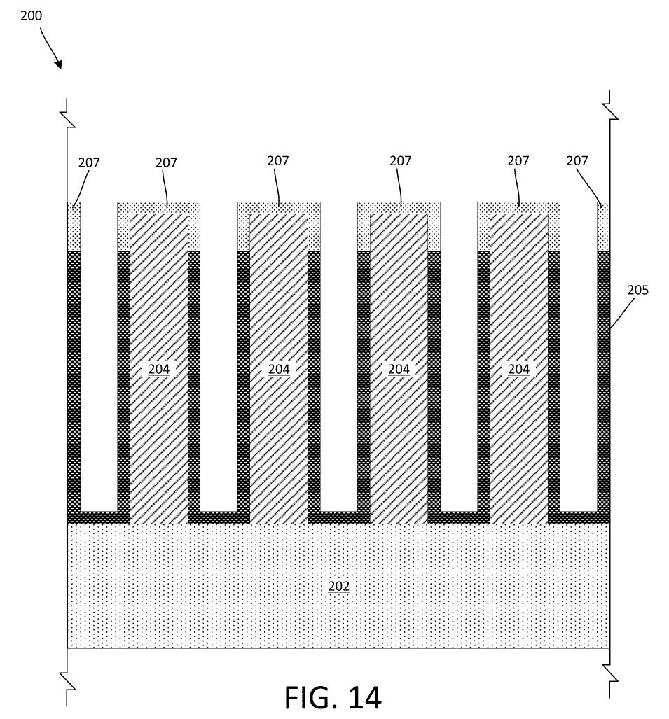

Referring now to FIG. 14, this figure is a partial cross-sectional view of the semiconductor device 200 of FIG. 13 at subsequent stage of the fabrication process, according to embodiments. As shown in FIG. 14, a suitable material removal process is performed to remove the sacrificial material layer 206.

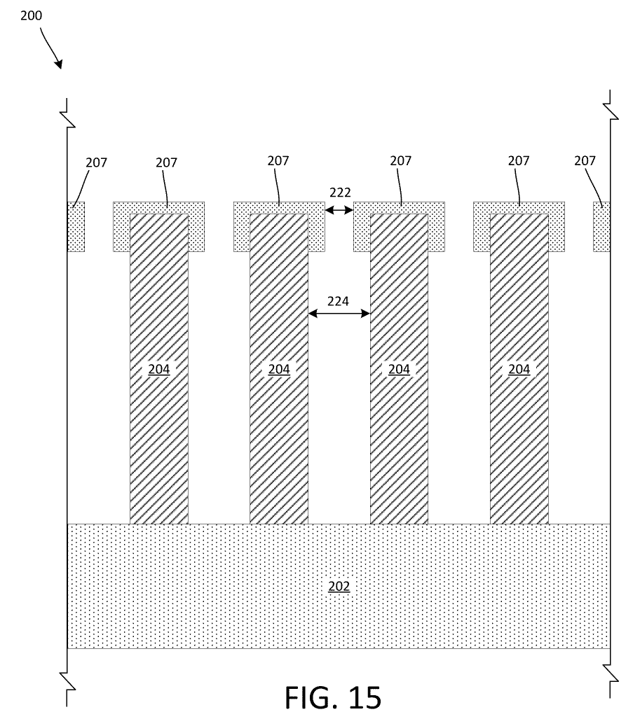

Referring now to FIG. 15, this figure is a partial cross-sectional view of the semiconductor device 200 of FIG. 14 at subsequent stage of the fabrication process, according to embodiments. As shown in FIG. 15, after the removal of the sacrificial material layer 206, a suitable material removal process is used to selectively remove the liner layer 205. Thus, after the removal of the liner layer 205, there is a first distance 222 between adjacent sections of the protuberance layers 207 that is less than a second distance 224 between adjacent metal lines 204.

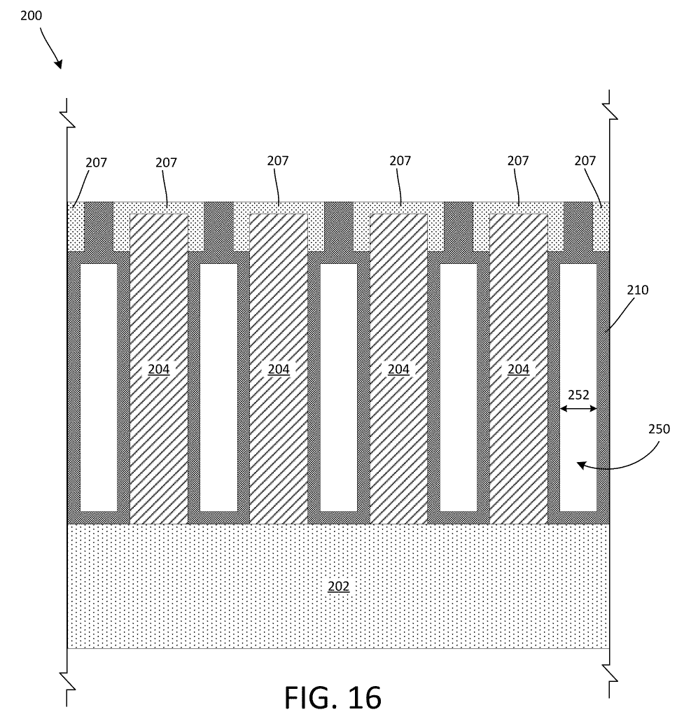

Referring now to FIG. 16, this figure is a partial cross-sectional view of the semiconductor device 200 of FIG. 15 at subsequent stage of the fabrication process, according to embodiments. As shown in FIG. 16, a material deposition process is performed to create a dielectric liner layer 210 on the sidewalls of the protuberance layers 207 and the sidewalls of the metal lines 204. It should be appreciated that any suitable dielectric material(s) may be used to form the dielectric liner layer 210. As discussed with respect to FIG. 15, the first distance 222 between adjacent sections of the protuberance layers 207 is less than a second distance 252 between adjacent metal lines 204. Thus, when the material of the dielectric liner layer 210 is deposited, the space (i.e., corresponding to the first distance 222 shown in FIG. 5) between the adjacent protuberance layers 207 will close off before completely filling in the space (i.e., corresponding to the second distance 250 shown in FIG. 15) between the adjacent metal lines 204, thus leaving an air gap 250 with a width of 252.

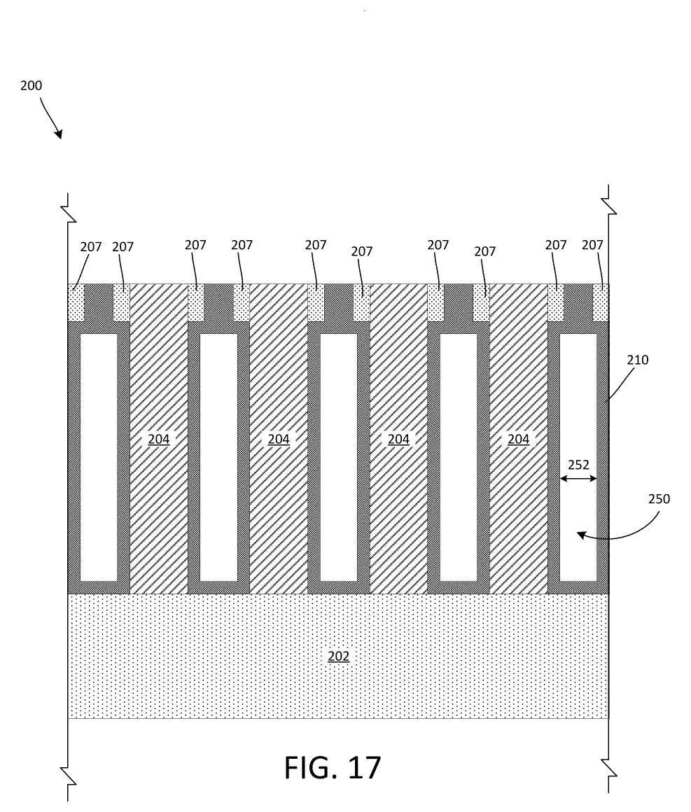

Referring now to FIG. 17, this figure is a partial cross-sectional view of the semiconductor device 200 of FIG. 16 at subsequent stage of the fabrication process, according to embodiments. As shown in FIG. 17, after the deposition of the dielectric liner layer 210 a suitable material removal process (e.g., CMP) is performed to planarize the top surface of the semiconductor device 200 and to remove excess material of both the protuberance layer 207 and the dielectric liner layer 210 that was previously formed on the top of the metal lines 204. In certain embodiments, the material of the protuberance layer 207 is removed to a sufficient extent to expose the top surfaces of the metal lines 204 (i.e., the portion of the protuberance layer 207 covering the metal lines 204 shown in FIG. 16). In contrast to the comparative example shown in FIG. 8 and as shown in the embodiments related to FIGS. 9-17, a larger air gap 250 having a larger width 252 is able to be formed owing to the protuberance layer 207. In this regard, less material of the dielectric liner layer 210 needs to be deposited (i.e., relative to the comparative example shown in FIG. 8) in order to close off (or pinch off) the upper portion of the dielectric liner layer 210 that is between the protuberance layer 207. As mentioned above, the dielectric constant of air is 1.0, which is significantly lower than that of any solid material used in semiconductor fabrication. Thus, incorporation of a relatively larger air gap 250 as shown in FIG. 17 (i.e., relative to air gap 150’ shown in FIG. 8) having a larger width 252 inside the dielectric liner layer 210 allows for the lowering of the overall effective dielectric constant for the semiconductor device 200, which may improve device performance.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A semiconductor device comprising:
a substrate;
a plurality of metal lines on the substrate;
a protuberance layer formed on upper portions of sidewalls of the metal lines; and
a liner layer formed between the metal lines and between the protuberance layer, the liner layer connecting the protuberance layer,
wherein an airgap exists in the liner layer below a bottom surface of the protuberance layer.

2. The semiconductor device of claim 1, wherein the protuberance layer comprises a dielectric material.

3. The semiconductor device of claim 1, wherein the protuberance layer comprises a metallic material.

4. The semiconductor device of claim 1, wherein the metal lines comprise Cu.

5. The semiconductor device of claim 1, wherein a distance between adjacent metal lines ranges from about 5-10 nm.

6. The semiconductor device of claim 1, herein a pitch of the metal lines ranges from about 10-20 nm.

7. A method of manufacturing a semiconductor device, the method comprising:
forming a plurality of metal lines on a substrate;
forming a protuberance layer on upper portions of sidewalls of the metal lines; and
forming a liner layer between the metal lines and between the protuberance layer, the liner layer connecting the protuberance layer,
wherein an airgap exists in the liner layer below a bottom surface of the protuberance layer.

8. The method of claim 7, further comprising, after forming the plurality of metal lines:
forming a sacrificial layer between the metal lines, where a top surface of the sacrificial layer is below a top surface of the metal layers, thereby leaving exposed top portions of the metal lines.

9. The method of claim 8, further comprising, after forming the sacrificial layer:
forming the protuberance layer continuously to cover the top surface of the sacrificial layer and the exposed top portions of the metal layers; and
selectively removing horizontal portions of the protuberance layer.

10. The method of claim 9, further comprising removing the sacrificial layer.

11. The method of claim 10, further comprising conformally depositing the liner layer after removing the sacrificial layer.

12. The method of claim 7, wherein the protuberance layer comprises a dielectric material.

13. The method of claim 7, further comprising, after forming the plurality of metal lines:
forming a sacrificial liner layer between the metal lines, the sacrificial liner layer covering the metal lines and the substrate.

14. The method of claim 13, further comprising, after forming the sacrificial liner layer,
forming a sacrificial layer between the sacrificial liner layer.

15. The method of claim 14, further comprising:
recessing the sacrificial layer to a level that is below a top surface of the metal layers.

16. The method of claim 15, further comprising, after recessing the sacrificial layer:
performing a process selected from the group consisting of plasma oxidation and plasma nitridation to chemically alter exposed upper portions of the sacrificial liner layer that are above the top surface of the metal layers to create the protuberance layer.

17. The method of claim 16, further comprising removing the sacrificial layer.

18. The method of claim 17, further comprising selectively removing the sacrificial liner layer without removing the protuberance layer.

19. The method of claim 18, further comprising, after removing the sacrificial liner layer, conformally depositing the liner layer.

20. The method of claim 19, further comprising planarizing the semiconductor device to expose the top surface of the metal layers.
